(19) United States
(12) Patent Application Publication
(10) Pub. No.: US 2025/0370247 A1
(43) Pub. Date: Dec. 4, 2025

(54) SYSTEMS FOR PATH COMPENSATION WITH A MOVING OBJECTIVE

(71) Applicant: ASML NETHERLANDS B.V., Veldhoven (NL)

(72) Inventor: Douglas C. CAPPELLI, Norwalk, CT (US)

(73) Assignee: ASML NETHERLANDS B.V., Veldhoven (NL)

(21) Appl. No.: 18/874,812

(22) PCT Filed: Sep. 15, 2023
(86) PCT No.: PCT/EP2023/075422

§ 371 Date: Dec. 13, 2024

Related U.S. Application Data
(60) Provisional application No. 63/410,700, filed on Sep. 28, 2022.

(51) Int. Cl. G02B 26/08; G03F 7/00

(52) U.S. Cl. CPC G02B 26/0816; G03F 7/70258; G03F 7/70358; G03F 7/706849; G03F 7/70825

(57) ABSTRACT

A mirror set having a first mirror, a second mirror, and a movable stage to which the mirror set is mounted to cause the first mirror and the second mirror to move together with the movable stage. The first mirror is configured to receive a beam at a first angle from an axis of the mirror set and the second mirror is configured to provide the beam at a second angle from the axis of the mirror set, the beam providing an output after reflection by the second mirror. Movement of the mirror set parallel to the axis results in a parallel shift of the output along the beam and movement of the mirror set perpendicular to the axis results in a perpendicular shift of the output perpendicular to the beam.

### CROSS-REFERENCE TO RELATED APPLICATIONS

This application claims priority of U.S. application 63/410,700 which was filed on 28 Sep. 2022 and which is incorporated herein in its entirety by reference.

### TECHNICAL FIELD

The description herein relates generally to optical systems utilized for measurement or metrology. More particularly, the disclosure includes apparatuses for compensating changes in a beam path in systems that have a moving objective.

### BACKGROUND

A lithographic projection apparatus can be used, for example, in the manufacture of integrated circuits (ICs). In such a case, a patterning device (e.g., a mask) may contain or provide a pattern corresponding to an individual layer of the IC (“design layout”), and this pattern can be transferred onto a target portion (e.g., comprising one or more dies) on a substrate (e.g., silicon wafer) that has been coated with a layer of radiation-sensitive material (“resist”), by methods such as irradiating the target portion through the pattern on the patterning device. In general, a single substrate contains a plurality of adjacent target portions to which the pattern is transferred successively by the lithographic projection apparatus, one target portion at a time. In one type of lithographic projection apparatuses, the pattern on the entire patterning device is transferred onto one target portion in one go; such an apparatus may also be referred to as a stepper. In an alternative apparatus, a step-and-scan apparatus can cause a projection beam to scan over the patterning device in a given reference direction (the “scanning” direction) while synchronously moving the substrate parallel or anti-parallel to this reference direction. Different portions of the pattern on the patterning device are transferred to one target portion progressively. Since, in general, the lithographic projection apparatus will have a reduction ratio M (e.g., 4), the speed F at which the substrate is moved will be 1/M times that at which the projection beam scans the patterning device. More information with regard to lithographic devices can be found in, for example, U.S. Pat. No. 6,046,792, incorporated herein by reference.

Prior to transferring the pattern from the patterning device to the substrate, the substrate may undergo various procedures, such as priming, resist coating and a soft bake. After exposure, the substrate may be subjected to other procedures (“post-exposure procedures”), such as a post-exposure bake (PEB), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, chemo-mechanical polishing, etc., all intended to finish off the individual layer of the device. If several layers are required in the device, then the whole procedure, or a variant thereof, is repeated for each layer. Eventually, a device will be present in each target portion on the substrate. These devices are then separated from one another by a technique such as dicing or sawing, whence the individual devices can be mounted on a carrier, connected to pins, etc.

Thus, manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, chemical-mechanical polishing, and ion implantation. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, etc.

As noted, lithography is a central step in the manufacturing of device such as ICs, where patterns formed on substrates define functional elements of the devices, such as microprocessors, memory chips, etc. Similar lithographic techniques are also used in the formation of flat panel displays, micro-electro mechanical systems (MEMS) and other devices.

As semiconductor manufacturing processes continue to advance, the dimensions of functional elements have continually been reduced while the amount of functional elements, such as transistors, per device has been steadily increasing over decades, following a trend referred to as “Moore's law.” At the current state of technology, layers of devices are manufactured using lithographic projection apparatuses that project a design layout onto a substrate using illumination from a deep-ultraviolet illumination source, creating individual functional elements having dimensions well below 100 nm, i.e. less than half the wavelength of the radiation from the illumination source (e.g., a 193 nm illumination source).

This process in which features with dimensions smaller than the classical resolution limit of a lithographic projection apparatus are printed, is can be referred to as low-k1 lithography, according to the resolution formula CD=k1×λ/NA, where λ is the wavelength of radiation employed (e.g., 248 nm or 193 nm), NA is the numerical aperture of projection optics in the lithographic projection apparatus, CD is the “critical dimension”—generally the smallest feature size printed-and kl is an empirical resolution factor. In general, the smaller k1 the more difficult it becomes to reproduce a pattern on the substrate that resembles the shape and dimensions planned by a designer in order to achieve particular electrical functionality and performance. To overcome these difficulties, sophisticated fine-tuning steps are applied to the lithographic projection apparatus, the design layout, or the patterning device. These include, for example, but not limited to, optimization of NA and optical coherence settings, customized illumination schemes, use of phase shifting patterning devices, optical proximity correction (OPC, sometimes also referred to as “optical and process correction”) in the design layout, or other methods generally defined as “resolution enhancement techniques” (RET). The term “projection optics” as used herein should be broadly interpreted as encompassing various types of optical systems, including refractive optics, reflective optics, apertures and catadioptric optics, for example. The term “projection optics” may also include components operating according to any of these design types for directing, shaping or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the patterning device, and/or optical components for shaping, adjusting and/or projecting the radiation after the radiation passes the patterning device. The projection optics generally exclude the source and the patterning device.

### SUMMARY

A system is disclosed that includes a mirror set comprising a first mirror, a second mirror, and a movable stage to which the mirror set is mounted to cause the first mirror and the second mirror to move together with the movable stage. The first mirror is configured to receive a beam at a first angle from an axis of the mirror set. The second mirror is configured to provide the beam at a second angle from the axis of the mirror set, the beam providing an output after reflection by the second mirror. Movement of the mirror set parallel to the axis results in a parallel shift of the output along the beam and movement of the mirror set perpendicular to the axis results in a perpendicular shift of the output perpendicular to the beam.

In some embodiments, the beam is a light beam from a light source in an optical scanning device and output can be a focus point of the light beam.

In some embodiments, the system can further include an objective to receive the output and configured to move with the movable stage where, during movement of the movable stage and objective, the output remains stationary with respect to the objective.

In some embodiments, an angular ratio that is a ratio between the first angle and the second angle determines a movement ratio of the movable stage that is an amount of movement at the output compared to an amount of movement at the movable stage. The angle between the input and the output can be 120 degrees thereby causing the ratio to be 1.

In some embodiments, the system can include an objective for receiving the output, the objective configured to move with the movable stage in a first direction. The system can also include a first static mirror configured to direct the beam to the objective where moving the movable stage and the objective along the first direction retains the position of the output at the objective along a second direction.

In some embodiments, the objective can be mechanically coupled to the movable stage or electronically controlled to move correspondingly to movement of the movable stage. Movement of the movable stage in the second direction can cause a corresponding movement of the output relative to objective.

In some embodiments, the system can further include an objective for receiving the output, the objective configured to move with the movable stage in a first direction and/or a second direction. A first static mirror can be configured to redirect the beam to the objective and a second static mirror can be configured to direct the beam to the first static mirror. Moving the movable stage and the objective to maintain a displacement along the first direction and along the second direction retains a position of the output at the objective.

In some embodiments, the system can further include a second static mirror configured to direct the beam to the mirror set and a second mirror set oriented perpendicular to and out of a plane of the mirror set and configured to direct the beam from the second mirror set to the mirror set. There can be a second movable stage to which the second mirror set is mounted and a third static mirror configured to direct the beam from the second mirror set to the second static mirror, where moving the second mirror set in the first direction allows adjustment of the output in the first direction, moving the second mirror set in the second direction allows adjustment of the output in the second direction, and moving the second mirror set in the third direction does not change a location of the output in the third direction.

In some embodiments, the system is configured for the second mirror set and the objective to move in the second direction relative to the mirror set, thereby causing the output to move along the second direction.

In some embodiments, the objective is further configured to move in the second direction independently of the mirror set, wherein maintaining a displacement between the second mirror set and the objective in the second direction retains the position of the output relative to the objective in the second direction.

In some embodiments, the system further includes an objective for receiving the output, the objective configured to move with the movable stage to maintain a same displacement between the objective and the movable stage in both a first direction and a third direction. The system can also include a first static mirror configured to direct the beam to the objective, a second static mirror configured to direct the beam to the first static mirror, and a folding mirror coupled to the movable stage and configured to turn the beam to be along a second direction, where moving the movable stage and the objective to maintain the displacement retains a position of the output at the objective along the second direction.

### BRIEF DESCRIPTION OF THE DRAWINGS

The accompanying drawings, which are incorporated in and constitute a part of this specification, show certain aspects of the subject matter disclosed herein and, together with the description, help explain some of the principles associated with the disclosed implementations. In the drawings,

FIG. 1 is a diagram of a dual objective metrology system having a moving objective, according to an embodiment of the present disclosure.

FIG. 2 is a diagram of a metrology system with a mirror set for directing light to/from an objective, according to an embodiment of the present disclosure.

FIG. 3 is a diagram of a mirror set that compensates for movement of a movable stage, according to an embodiment of the present disclosure.

FIG. 4 is a diagram of a mirror set that compensates for movement of a movable stage and delivers a beam to an objective, according to an embodiment of the present disclosure.

FIGS. 5A-C are diagrams of alternative configurations of mirror sets, according to various embodiments of the present disclosure.

FIG. 6 is a diagram of a mirror set that allows for movement with two degrees of freedom, according to an embodiment of the present disclosure.

FIG. 7 is a diagram of multiple mirror sets that allow for movement perpendicular to the plane of one of the mirror sets, according to an embodiment of the present disclosure.

FIG. 8 is a diagram of a mirror set that includes a turning mirror for the objective, according to an embodiment of the present disclosure.

FIG. 9 is a block diagram of an example computer system, according to an embodiment of the present disclosure.

FIG. 10 is a schematic diagram of a lithographic projection apparatus, according to an embodiment of the present disclosure.

FIG. 11 is a schematic diagram of another lithographic projection apparatus, according to an embodiment of the present disclosure.

FIG. 12 is a detailed view of the lithographic projection apparatus, according to an embodiment of the present disclosure.

FIG. 13 is a detailed view of the source collector module of the lithographic projection apparatus, according to an embodiment of the present disclosure.

### DETAILED DESCRIPTION

Metrology system (e.g., electron beam, optical, etc.) can be utilized to measure and/or characterize printed products (e.g., semiconductor chip wafers) or other manufactured components. For example, during or after the manufacture of a wafer for semiconductor processors, memory, etc., the features printed or etched on the wafer can be measured to determine how well the product matches a target pattern. These measurements can include measuring aspects such as critical dimensions (CDs), overlay, edge placement error (EPE), etc. The present disclosure primarily relates to measurements with optical metrology systems that provide light to the surface of the target product and then detect and analyze the light to generate an image of the target for further analysis.

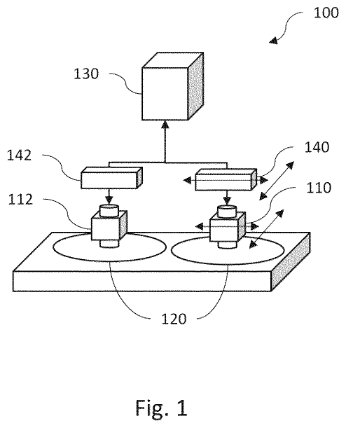

FIG. 1 is a diagram of a dual objective metrology system having a moving objective, according to an embodiment of the present disclosure. Some metrology systems can allow parallel measurements of multiple targets (e.g., wafers) through two separate objectives. As shown in FIG. 1, a metrology system 100 can include a source/sensor 130 whose illumination light is split between two objectives 110,112. This architecture can have at least one of the objectives able to move, for example to enable the ability to measure targets 120 separated by varying distance, for example either due to being separate targets, or due to misalignments between two wafers that are being measured simultaneously. The split light can be directed through two mirror sets 140, 142, with at least portions of one mirror set (e.g., mirror set 140) able to move with objective 110.

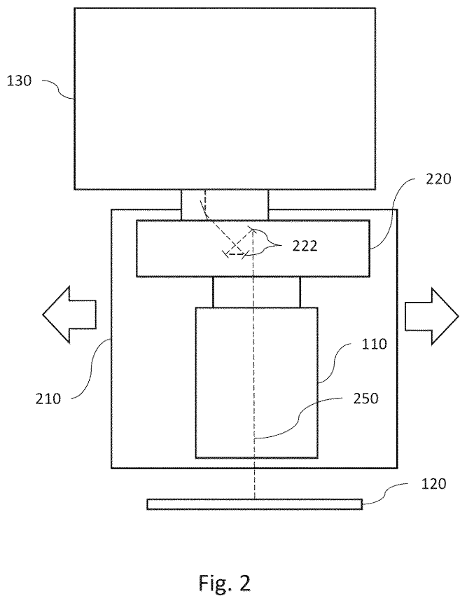

FIG. 2 is a diagram of a metrology system with a mirror set for directing light to/from an objective, according to an embodiment of the present disclosure. FIG. 2 includes numerous features described with regard to FIG. 1 (e.g., objective 110, target 120, source/sensor 130). As also shown by the simplified example in FIG. 2, the present disclosure provides numerous embodiments that permit a light beam 250 from a source/sensor 130 to be delivered to an objective 110. In various embodiments, this can be accomplished by having the objective 110 move relative to some components of the system but be stationary relative to at least some portions of a movable stage 210 that can hold a mirror set 220. For example, the objective 110 can be fixed to the movable stage 210 so they move together or, in other embodiments, objective 110 can be independently controlled to move in synch with some portions of the mirror set 220.

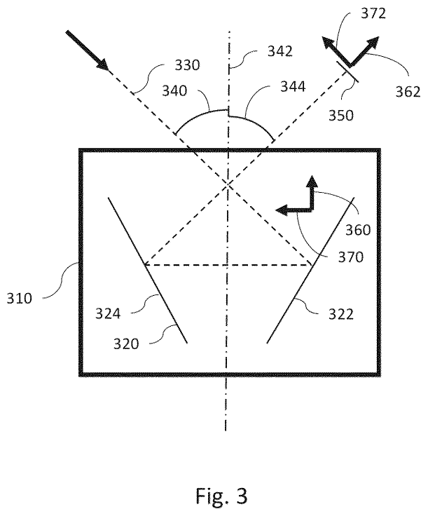

FIG. 3 is a diagram of a mirror set that compensates for movement of a movable stage, according to an embodiment of the present disclosure. FIG. 3 depicts a system, which, because of the geometry of the example mirrors 222 in mirror set 220, can be insensitive to (also referred to herein as “compensating for”) movement of the movable stage in certain directions. Such a system can enable a shifted light beam 330 (e.g., shifted relative to a movable stage) to reach a target and/or light from a target to return along the same path to a sensor. In some embodiments, the beam can be a light beam from a light source in an optical scanning device or metrology system such as those depicted in FIGS. 1 and 2. The system depicted in FIG. 3 includes a mirror set 320 having a first mirror 322 (taken here to receive a light beam 330 illustrated by the dashed line) and a second mirror 324 (shown here as providing the beam 330 after reflecting off first mirror 322 and second mirror 324). There can be a movable stage 310 to which the mirror set 320 can be mounted to cause the first mirror 322 and the second mirror 324 to move together with the movable stage 310. A movable stage can be, for example, an optical table, a plate, or any other object to which the mirrors/optics can be mounted and can be configured to move in one or more directions, such as with motors, on tracks or rails, with belts, with piezoelectric transducers, etc. As shown, first mirror 322 can be configured to receive beam 330 at first angle 340 from an axis 342 of the mirror set. First angle 340 can be any angle between 0 and 180, for example, +75, 60, 45, 30, 15 or degrees. Similarly, second mirror 324 can be configured to provide beam 330 at a second angle 344 from the axis 342 of the mirror set 320, with the beam 330 providing an output 350 (e.g., a focus point of a light beam, a light spot, etc.) after reflection by the second mirror 324. Output 350 can be at any point along the beam path after the final mirror in the mirror set.

In general, movement (e.g., parallel movement 360) of the mirror set 320 parallel to axis 342 can result in a parallel shift 362 of the output 350 along the beam (i.e., parallel to the beam direction at the target). For example, as shown, movement in the Y direction (along axis 342) acts to shorten/lengthen the beam path without changing any angles of reflection. In the example where the output is a focus point of the light beam, this has the effect of moving the focus point but without moving the focus point perpendicular to the beam path. Similarly, movement 370 of the mirror set 320 perpendicular to axis 342 can result in a perpendicular shift 372 of the output 350 perpendicular to the beam. An angular ratio (which can be the ratio between the first angle 340 and the second angle 344) can determine a movement ratio of the movable stage 310. The movement ratio is the amount of movement at the output compared to the amount of movement of the movable stage. Specifically, in embodiments where first angle 340 and second angle 344 are the same, the ratio can change from 1.73 when the angles are both 30 degrees, to 1.0 when 60 degrees, to 0.52 when 75 degrees, etc. For example, if both angles are 60 degrees, then 1 mm of parallel movement 360 causes 1 mm of parallel shift 362 of output 350. While in some embodiments a ratio other than 1.0 may be useful, in most embodiments the angle between the input and the output (i.e., the sum of first angle 340 and second angle 344) is 120 degrees thereby causing the ratio to be 1.0. In embodiments where the angles are different, this can cause a compound motion where, e.g., in response to parallel movement 360, output 350 can exhibit a parallel shift 362 but also a perpendicular shift 372.

Though not shown in FIG. 3, in any of the embodiments herein, the system can include an objective to receive the output and configured to move with the movable stage. As also shown in numerous embodiments herein, during movement of the movable stage and objective, the output can remain stationary with respect to the objective. As described previously, any of the objectives herein can be configured to move with the movable stage by being mechanically coupled to the movable stage or can be independently (e.g., electronically) controlled to move correspondingly to movement of the movable stage. As used herein, “mechanically coupled” or just “coupled” means that there is a rigid connection (e.g., the objective is somehow fastened to the movable stage). While the objective can be a lens that focuses on a wafer or other target, the objective can be any other optical component such as, lenses, mirrors, etc. or any component that may need the beam at a certain focal position. Also, though the objective is recited as included in many embodiments, the present disclosure contemplates that the objective is not required to be included in any embodiment's particular physical system. For example, some embodiments can include only the mirror system, with the objective, movable stages, etc. supplied separately for use as described herein.

A number of embodiments herein are described with reference to an orthogonal X-Y-Z coordinate system. This is for explanatory purposes only and as such no embodiment requires any particular orientation. The X-direction is referred to herein as a “first direction” (and can be positive or negative) and the Z-direction is referred to herein as a “second direction” (and can be positive or negative). Some embodiments can include a Y-direction that is referred to herein as a “third direction” (and can be positive or negative).

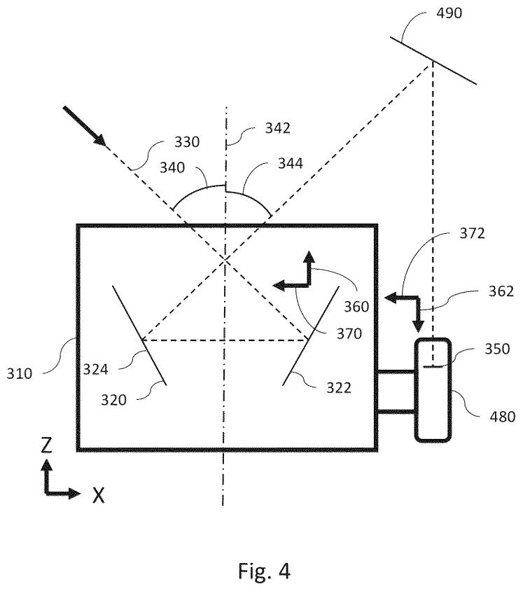

FIG. 4 is a diagram of a mirror set that compensates for movement of a movable stage and

delivers a beam to an objective, according to an embodiment of the present disclosure. This mirror set is depicted as being in an X-Z plane. FIG. 4 is also similar to FIG. 3 with many of the elements reproduced therefrom. However, the embodiment depicted in FIG. 4 also includes an objective 480 for receiving output 350. The objective 480 can be configured to move with the movable stage 310 in a first direction, for example by mechanical coupling or by being electronically controlled to move correspondingly to movement of the movable stage 310. Some embodiments can include a first static mirror 490 configured to direct the beam 330 to the objective 480. As used herein, the term “static” means “stationary relative to the input light beam” (e.g., stationary relative to the light source, the last optical component before the beam reaches the mirror set, etc.). While a static mirror may be capable of movement in some embodiments, as used herein any static mirrors are considered to remain in place with respect to any movements of the movable stages.

With the first static mirror 490 essentially redirecting the output 350 to objective 480, moving the movable stage and the objective 480 along the first direction (e.g., the X direction) retains the position of the output 350 at the objective 480 along a second direction (e.g., the Z direction). Similarly, in some embodiments, movement of the movable stage 310 in the second direction can cause a corresponding movement of the output 350 relative to objective 480.

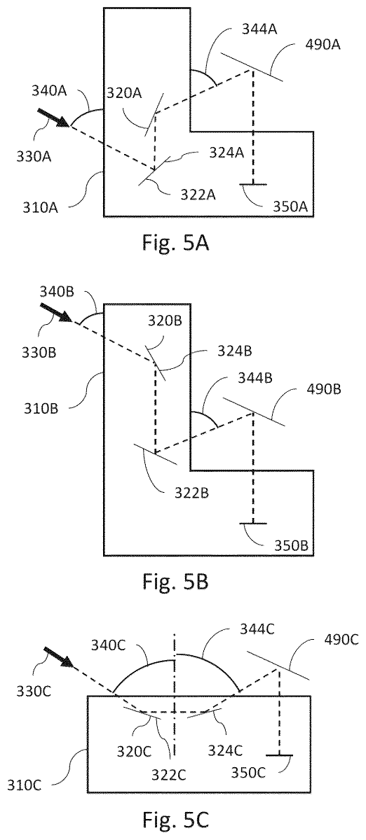

FIGS. 5A-C are diagrams of alternative configurations of mirror sets, according to various embodiments of the present disclosure. These alternative configurations perform similar functions as the embodiment of FIG. 4. However, as can be seen, the various mirrors and movable stages in the mirror sets have different geometries. Element numbers are reproduced from corresponding elements of FIG. 4, but with FIG. 5 designations (A, B, or C) appended (e.g., movable stage 310A in FIG. 5A is similar to movable stage 310 in FIG. 4).

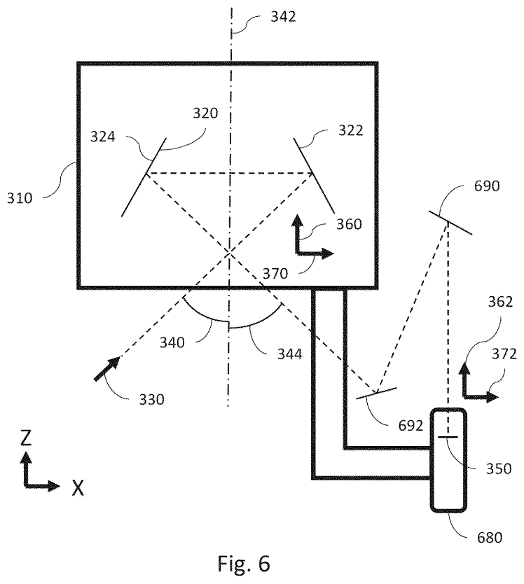

FIG. 6 is a diagram of a mirror set that allows for movement with two degrees of freedom, according to an embodiment of the present disclosure. This embodiment is similar to that of FIG. 3, but in particular with mirror set 320 inverted and the addition of static mirrors 690, 692 and objective 680. Objective 680 can receive the output 350, with the objective 680 configured to move with the movable stage 310 in a first direction (e.g., X direction) and/or a second direction (e.g., Z direction). The system can also include a first static mirror 690 configured to redirect the beam 330 to the objective 680 and a second static mirror 692 configured to direct the beam 330 to the first static mirror 690.

The system can be configured such that moving the movable stage 310 and the objective 680 to maintain a displacement along the first direction and along the second direction retains the position of the output 350 at the objective 680. As used herein, the phrase “maintaining a displacement” means that certain elements of the system (e.g., movable stage 310 and objective 680) move together, e.g., via mechanical coupling or independent but synchronized control. This also means that the movable stage 310 and objective 680 are free to move in the X-Z plane as shown with the output 350 remaining at the same place in the objective 680.

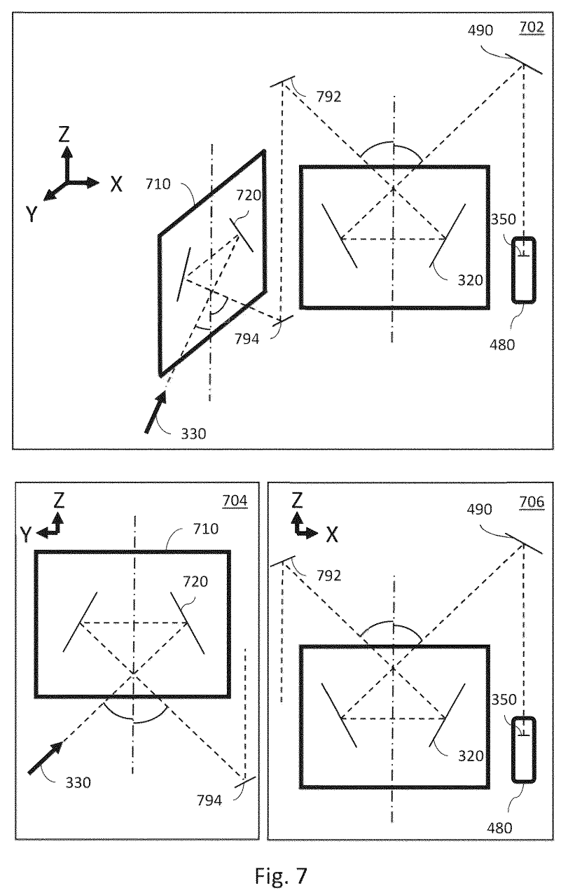

FIG. 7 is a diagram of multiple mirror sets that allow for movement perpendicular to the plane of one of the mirror sets, according to an embodiment of the present disclosure. FIG. 7 includes diagram 702 depicting a three-dimensional view of an embodiment having multiple mirror sets disposed in orthogonal planes. Also shown are diagram 704 illustrating components in the Y-Z plane and diagram 706 illustrating components in the X-Z plane. The depicted system builds on the embodiment of FIG. 4 (having a mirror set in an X-Z plane) by including another mirror set in an orthogonal plane (e.g., the Y-Z plane) that is therefore configured to allow movement of the objective in the Y direction. FIG. 7 can also be understood by folding diagram 704 to be 90 degrees “out of the page” similar to that depicted in diagram 702. Also, the beam 330 leaving diagram 704 is the input beam in diagram 706.

In addition to the elements depicted in FIG. 4 (some of which are reproduced in diagrams 702, 704, and 706) some embodiments can include a second static mirror 792 configured to direct the beam 330 to the mirror set 320 (in diagram 706). Also shown is a second mirror set 720 (in diagram 704) oriented perpendicular to, and out of the plane of, mirror set 320 and configured to direct the beam 330 from the second mirror set 720 to mirror set 320. A second movable stage 710 is shown to which the second mirror set 720 can be mounted. Second movable stage 710 and second mirror set 720 can be similar to the movable stage and mirror set of FIG. 4, but in this embodiment second mirror set 720 is inverted. There can also be a third static mirror 794 configured to direct the beam 330 from the second mirror set 720 to the second static mirror 792. The embodiment of FIG. 7 is therefore configured such that moving the second mirror set 720 in the second direction allows adjustment of the output 350 in the second direction, moving the second mirror set 720 in the third direction allows adjustment of the output 350 in the third direction, and moving the second mirror 720 set in the first direction does not change a location of the output 350 in the first direction. Similarly, moving the first mirror set 320 set in the first direction allows adjustment of the output 350 in the first direction, moving the first mirror set 320 in the second direction allows adjustment of the output 350 in the second direction, and moving the first mirror set 320 in the third direction does not change a location of the output 350 in the third direction.

In some embodiments, the system can be configured for the second mirror set 720 and the objective 480 to move in the second direction relative to the mirror set 320, thereby causing the output 350 to move along the second direction. In other embodiments, mirror set 320 and objective 480 can move in the second direction relative to the second mirror set 720, thereby also causing the output 350 to move along the second direction.

In some embodiments, objective 480 can be further configured to move in the second direction independently of the mirror set. In such embodiments, maintaining a displacement between the second mirror set 720 and the objective 480 in the second direction retains the position of the output 350 relative to the objective 480 in the second direction.

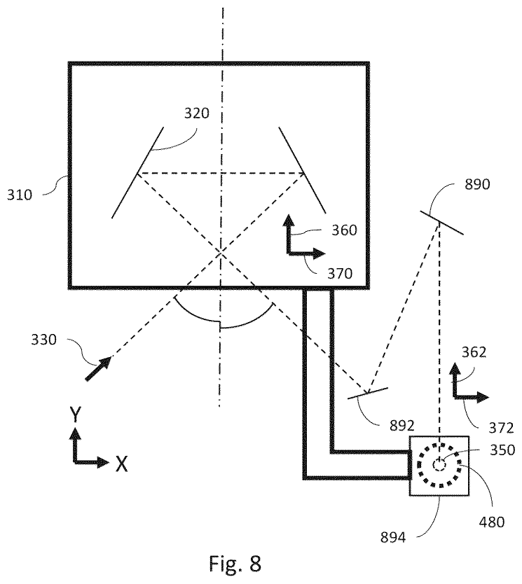

FIG. 8 is a diagram of a mirror set that includes a turning mirror for the objective, according to an embodiment of the present disclosure. The embodiment of FIG. 8 depicts a mirror set that can have the objective oriented perpendicular to the plane of the mirror set. For example, mirror set 320 can be mounted horizontally (e.g., in the X-Y plane) with the objective 480 oriented vertically (e.g., along Z). FIG. 8 also builds on the embodiment of FIG. 3 but can further include an objective 480 (similar to that in FIG. 4) for receiving the output 350. The objective 480 can be configured to move with the movable stage 310 to maintain a same displacement between the objective 480 and the movable stage 310 in both a first direction (e.g., in X) and a third direction (e.g., along Y). The system can also include a first static mirror 890 configured to direct the beam 330 to the objective 480 and a second static mirror 892 configured to direct the beam 330 to the first static mirror 890.

The system can also include a folding mirror 894 coupled to the movable stage 310 and configured to turn the beam 330 to be along a second direction (e.g., along Z). The folding mirror can be any type of mirror but is described herein as “folding” in that the folding mirror “folds” the beam from being in the X-Y plane, as shown, to going along Z (or any other direction in other embodiments). Accordingly, in such embodiments, moving the movable stage 310 and the objective 480 to maintain the displacement can retain the position of the output 350 at the objective 480 along the second direction (e.g., along Z).

As previously mentioned, the embodiments disclosed herein can improve measurements and/or metrology of devices manufactured such as with lithographic processes. Examples of lithographic systems that the disclosed embodiments can be used with are described below.

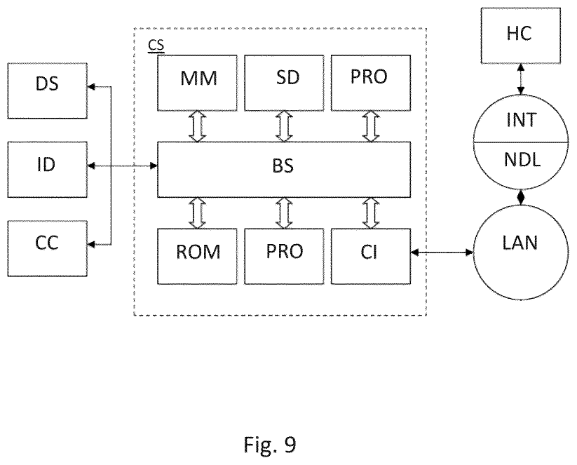

FIG. 9 is a block diagram of an example computer system CS, according to an embodiment of the present disclosure.

Computer system CS includes a bus BS or other communication mechanism for communicating information, and a processor PRO (or multiple processor) coupled with bus BS for processing information. Computer system CS also includes a main memory MM, such as a random access memory (RAM) or other dynamic storage device, coupled to bus BS for storing information and instructions to be executed by processor PRO. Main memory MM also may be used for storing temporary variables or other intermediate information during execution of instructions to be executed by processor PRO. Computer system CS further includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a cathode ray tube (CRT) or flat panel or touch panel display for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

According to one embodiment, portions of one or more methods described herein may be performed by computer system CS in response to processor PRO executing one or more sequences of one or more instructions contained in main memory MM. Such instructions may be read into main memory MM from another computer-readable medium, such as storage device SD. Execution of the sequences of instructions contained in main memory MM causes processor PRO to perform the process steps described herein. One or more processors in a multi-processing arrangement may also be employed to execute the sequences of instructions contained in main memory MM. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM. Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have instructions recorded thereon. The instructions, when executed by a computer, can implement any of the features described herein. Transitory computer-readable media can include a carrier wave or other propagating electromagnetic signal.

Various forms of computer readable media may be involved in carrying one or more sequences of one or more instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

Computer system CS may also include a communication interface CI coupled to bus BS. Communication interface CI provides a two-way data communication coupling to a network link NDL that is connected to a local network LAN. For example, communication interface CI may be an integrated services digital network (ISDN) card or a modem to provide a data communication connection to a corresponding type of telephone line. As another example, communication interface CI may be a local area network (LAN) card to provide a data communication connection to a compatible LAN. Wireless links may also be implemented. In any such implementation, communication interface CI sends and receives electrical, electromagnetic or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) both use electrical, electromagnetic or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT, network data link NDL, local network LAN and communication interface CI. One such downloaded application may provide all or part of a method described herein, for example. The received code may be executed by processor PRO as it is received, and/or stored in storage device SD, or other non-volatile storage for later execution. In this manner, computer system CS may obtain application code in the form of a carrier wave.

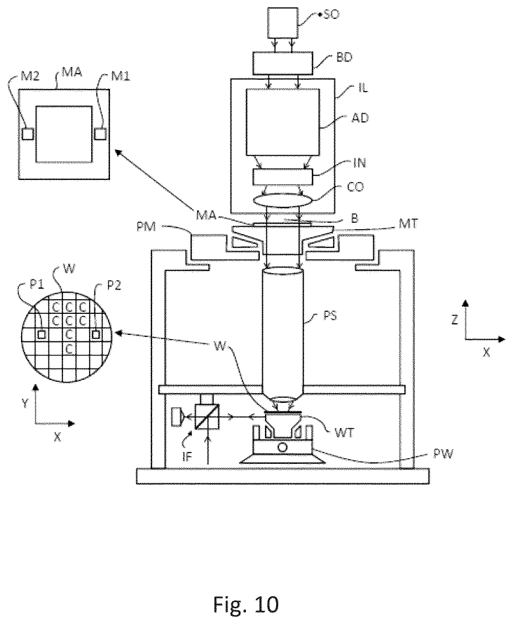

FIG. 10 is a schematic diagram of a lithographic projection apparatus, according to an embodiment of the present disclosure.

The lithographic projection apparatus can include an illumination system IL, a first object table MT, a second object table WT, and a projection system PS.

Illumination system IL, can condition a beam B of radiation. In this particular case, the illumination system also comprises a radiation source SO.

First object table (e.g., patterning device table) MT can be provided with a patterning device holder to hold a patterning device MA (e.g., a reticle), and connected to a first positioner to accurately position the patterning device with respect to item PS.

Second object table (substrate table) WT can be provided with a substrate holder to hold a substrate W (e.g., a resist-coated silicon wafer), and connected to a second positioner to accurately position the substrate with respect to item PS.

Projection system (“lens”) PS (e.g., a refractive, catoptric or catadioptric optical system) can image an irradiated portion of the patterning device MA onto a target portion C (e.g., comprising one or more dies) of the substrate W.

As depicted herein, the apparatus can be of a transmissive type (i.e., has a transmissive patterning device). However, in general, it may also be of a reflective type, for example (with a reflective patterning device). The apparatus may employ a different kind of patterning device to classic mask; examples include a programmable mirror array or LCD matrix.

The source SO (e.g., a mercury lamp or excimer laser, LPP (laser produced plasma) EUV source) produces a beam of radiation. This beam is fed into an illumination system (illuminator) IL, either directly or after having traversed conditioning apparatuses, such as a beam expander Ex, for example. The illuminator IL may comprise adjusting device AD for setting the outer and/or inner radial extent (commonly referred to as o-outer and o-inner, respectively) of the intensity distribution in the beam. In addition, it will generally comprise various other components, such as an integrator IN and a condenser CO. In this way, the beam B impinging on the patterning device MA has a desired uniformity and intensity distribution in its cross-section.

In some embodiments, source SO may be within the housing of the lithographic projection apparatus (as is often the case when source SO is a mercury lamp, for example), but that it may also be remote from the lithographic projection apparatus, the radiation beam that it produces being led into the apparatus (e.g., with the aid of suitable directing mirrors); this latter scenario can be the case when source SO is an excimer laser (e.g., based on KrF, ArF or F2 lasing).

The beam PB can subsequently intercept patterning device MA, which is held on a patterning device table MT. Having traversed patterning device MA, the beam B can pass through the lens PL, which focuses beam B onto target portion C of substrate W. With the aid of the second positioning apparatus (and interferometric measuring apparatus IF), the substrate table WT can be moved accurately, e.g., so as to position different target portions C in the path of beam PB. Similarly, the first positioning apparatus can be used to accurately position patterning device MA with respect to the path of beam B, e.g., after mechanical retrieval of the patterning device MA from a patterning device library, or during a scan. In general, movement of the object tables MT, WT can be realized with the aid of a long-stroke module (coarse positioning) and a short-stroke module (fine positioning). However, in the case of a stepper (as opposed to a step-and-scan tool) patterning device table MT may just be connected to a short stroke actuator, or may be fixed.

The depicted tool can be used in two different modes, step mode and scan mode. In step mode, patterning device table MT is kept essentially stationary, and an entire patterning device image is projected in one go (i.e., a single “flash”) onto a target portion C. Substrate table WT can be shifted in the x and/or y directions so that a different target portion C can be irradiated by beam PB.

In scan mode, essentially the same scenario applies, except that a given target portion C is not exposed in a single “flash.” Instead, patterning device table MT is movable in a given direction (the so-called “scan direction”, e.g., the y direction) with a speed v, so that projection beam B is caused to scan over a patterning device image; concurrently, substrate table WT is simultaneously moved in the same or opposite direction at a speed V=Mv, in which M is the magnification of the lens PL (typically, M=1/4 or 1/5). In this manner, a relatively large target portion C can be exposed, without having to compromise on resolution.

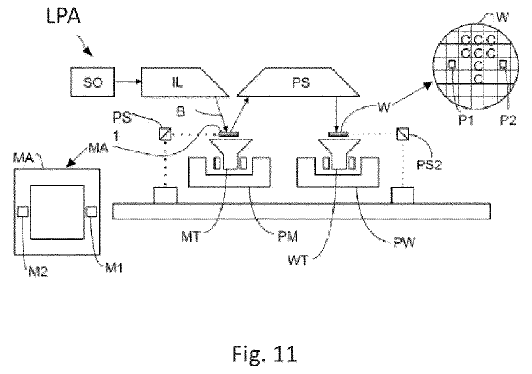

FIG. 11 is a schematic diagram of another lithographic projection apparatus (LPA), according to an embodiment of the present disclosure.

LPA can include source collector module SO, illumination system (illuminator) IL configured to condition a radiation beam B (e.g., EUV radiation), support structure MT, substrate table WT, and projection system PS.

Support structure (e.g., a patterning device table) MT can be constructed to support a patterning device (e.g., a mask or a reticle) MA and connected to a first positioner PM configured to accurately position the patterning device;

Substrate table (e.g., a wafer table) WT can be constructed to hold a substrate (e.g., a resist coated wafer) W and connected to a second positioner PW configured to accurately position the substrate.

Projection system (e.g., a reflective projection system) PS can be configured to project a pattern imparted to the radiation beam B by patterning device MA onto a target portion C (e.g., comprising one or more dies) of the substrate W.

As here depicted, LPA can be of a reflective type (e.g., employing a reflective patterning device). It is to be noted that because most materials are absorptive within the EUV wavelength range, the patterning device may have multilayer reflectors comprising, for example, a multi-stack of molybdenum and silicon. In one example, the multi-stack reflector has a 40 layer pairs of molybdenum and silicon where the thickness of each layer is a quarter wavelength. Even smaller wavelengths may be produced with X-ray lithography. Since most material is absorptive at EUV and x-ray wavelengths, a thin piece of patterned absorbing material on the patterning device topography (e.g., a TaN absorber on top of the multi-layer reflector) defines where features would print (positive resist) or not print (negative resist).

Illuminator IL can receive an extreme ultraviolet radiation beam from source collector module SO. Methods to produce EUV radiation include, but are not necessarily limited to, converting a material into a plasma state that has at least one element, e.g., xenon, lithium or tin, with one or more emission lines in the EUV range. In one such method, often termed laser produced plasma (“LPP”) the plasma can be produced by irradiating a fuel, such as a droplet, stream or cluster of material having the line-emitting element, with a laser beam. Source collector module SO may be part of an EUV radiation system including a laser for providing the laser beam exciting the fuel. The resulting plasma emits output radiation, e.g., EUV radiation, which is collected using a radiation collector, disposed in the source collector module. The laser and the source collector module may be separate entities, for example when a CO2 laser is used to provide the laser beam for fuel excitation.

In such cases, the laser may not be considered to form part of the lithographic apparatus and the radiation beam can be passed from the laser to the source collector module with the aid of a beam delivery system comprising, for example, suitable directing mirrors and/or a beam expander. In other cases, the source may be an integral part of the source collector module, for example when the source is a discharge produced plasma EUV generator, often termed as a DPP source.

Illuminator IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross section.

The radiation beam B can be incident on the patterning device (e.g., mask) MA, which is held on the support structure (e.g., patterning device table) MT, and is patterned by the patterning device. After being reflected from the patterning device (e.g., mask) MA, the radiation beam B passes through the projection system PS, which focuses the beam onto a target portion C of the substrate W. With the aid of the second positioner PW and position sensor PS2 (e.g., an interferometric device, linear encoder or capacitive sensor), the substrate table WT can be moved accurately, e.g., so as to position different target portions C in the path of radiation beam B. Similarly, the first positioner PM and another position sensor PS1 can be used to accurately position the patterning device (e.g., mask) MA with respect to the path of the radiation beam B. Patterning device (e.g., mask) MA and substrate W may be aligned using patterning device alignment marks M1, M2 and substrate alignment marks P1, P2.

The depicted apparatus LPA could be used in at least one of the following modes, step mode, scan mode, and stationary mode.

In step mode, the support structure (e.g., patterning device table) MT and the substrate table WT are kept essentially stationary, while an entire pattern imparted to the radiation beam is projected onto a target portion C at one time (i.e. a single static exposure). The substrate table WT is then shifted in the X and/or Y direction so that a different target portion C can be exposed.

In scan mode, the support structure (e.g., patterning device table) MT and the substrate table WT are scanned synchronously while a pattern imparted to the radiation beam is projected onto target portion C (i.e. a single dynamic exposure). The velocity and direction of substrate table WT relative to the support structure (e.g., patterning device table) MT may be determined by the (de-)magnification and image reversal characteristics of the projection system PS.

In stationary mode, the support structure (e.g., patterning device table) MT is kept essentially stationary holding a programmable patterning device, and substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array.

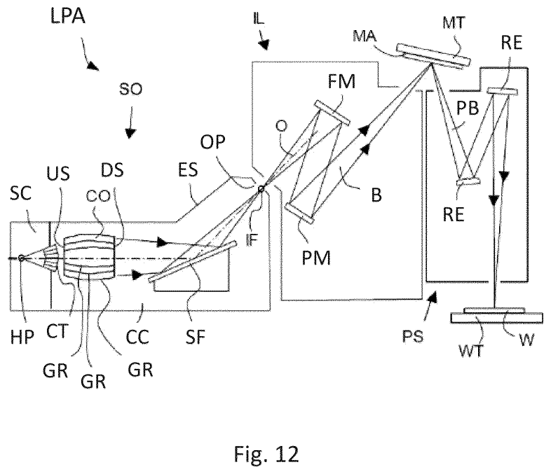

FIG. 12 is a detailed view of the lithographic projection apparatus, according to an embodiment of the present disclosure.

As shown, LPA can include the source collector module SO, the illumination system IL, and the projection system PS. The source collector module SO is constructed and arranged such that a vacuum environment can be maintained in an enclosing structure ES of the source collector module SO. An EUV radiation emitting hot plasma HP may be formed by a discharge produced plasma source. EUV radiation may be produced by a gas or vapor, for example Xe gas, Li vapor or Sn vapor in which the hot plasma HP is created to emit radiation in the EUV range of the electromagnetic spectrum. The hot plasma HP is created by, for example, an electrical discharge causing at least partially ionized plasma. Partial pressures of, for example, 10 Pa of Xe, Li, Sn vapor or any other suitable gas or vapor may be required for efficient generation of the radiation. In an embodiment, a plasma of excited tin (Sn) is provided to produce EUV radiation.

The radiation emitted by the hot plasma HP is passed from a source chamber SC into a collector chamber CC via an optional gas barrier or contaminant trap CT (in some cases also referred to as contaminant barrier or foil trap) which is positioned in or behind an opening in source chamber SC. The contaminant trap CT may include a channel structure. Contamination trap CT may also include a gas barrier or a combination of a gas barrier and a channel structure. The contaminant trap or contaminant barrier CT further indicated herein at least includes a channel structure, as known in the art.

The collector chamber CC may include a radiation collector CO which may be a so-called grazing incidence collector. Radiation collector CO has an upstream radiation collector side US and a downstream radiation collector side DS. Radiation that traverses radiation collector CO can be reflected off a grating spectral filter SF to be focused in a virtual source point IF along the optical axis indicated by the dot-dashed line ‘O’. The virtual source point IF can be referred to as the intermediate focus, and the source collector module can be arranged such that the intermediate focus IF is located at or near an opening OP in the enclosing structure ES. The virtual source point IF is an image of the radiation emitting plasma HP.

Subsequently the radiation traverses the illumination system IL, which may include a facetted field mirror device FM and a facetted pupil mirror device pm arranged to provide a desired angular distribution of the radiation beam B, at the patterning device MA, as well as a desired uniformity of radiation amplitude at the patterning device MA. Upon reflection of the beam of radiation B at the patterning device MA, held by the support structure MT, a patterned beam PB is formed and the patterned beam PB is imaged by the projection system PS via reflective elements RE onto a substrate W held by the substrate table WT.

More elements than shown may generally be present in illumination optics unit IL and projection system PS. The grating spectral filter SF may optionally be present, depending upon the type of lithographic apparatus. Further, there may be more mirrors present than those shown in the figures, for example there may be 1-6 additional reflective elements present in the projection system PS.

Collector optic CO can be a nested collector with grazing incidence reflectors GR, just as an example of a collector (or collector mirror). The grazing incidence reflectors GR are disposed axially symmetric around the optical axis O and a collector optic CO of this type may be used in combination with a discharge produced plasma source, often called a DPP source.

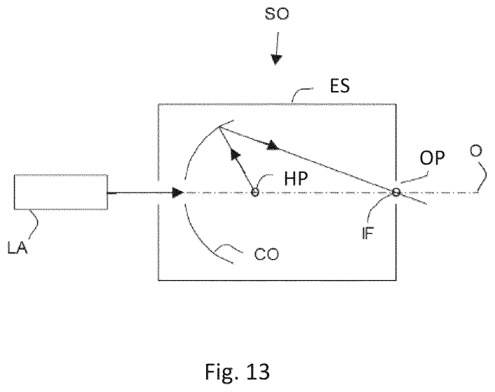

FIG. 13 is a detailed view of source collector module SO of lithographic projection apparatus LPA, according to an embodiment of the present disclosure.

Source collector module SO may be part of an LPA radiation system. A laser LA can be arranged to deposit laser energy into a fuel, such as xenon (Xe), tin (Sn) or lithium (Li), creating the highly ionized plasma HP with electron temperatures of several 10's of eV. The energetic radiation generated during de-excitation and recombination of these ions is emitted from the plasma, collected by a near normal incidence collector optic CO and focused onto the opening OP in the enclosing structure ES.

The embodiments may further be described using the following clauses:
1. A system comprising:
a mirror set comprising a first mirror and a second mirror; and
a movable stage to which the mirror set is mounted to cause the first mirror and the second mirror to move together with the movable stage,
wherein the first mirror is configured to receive a beam at a first angle from an axis of the mirror set,
   wherein the second mirror is configured to provide the beam at a second angle from the axis of the mirror set, the beam providing an output after reflection by the second mirror,
   wherein movement of the mirror set parallel to the axis results in a parallel shift of the output along the beam, and
   wherein movement of the mirror set perpendicular to the axis results in a perpendicular shift of the output perpendicular to the beam.
2. The system of clause 1, wherein the beam is a light beam from a light source in an optical scanning device.
3. The system of clause 2, wherein the output is a focus point of the light beam.
4. The system of clause 1, further comprising an objective to receive the output and configured to move with the movable stage, wherein during movement of the movable stage and objective the output remains stationary with respect to the objective.
5. The system of clause 1, wherein an angular ratio that is a ratio between the first angle and the second angle determines a movement ratio of the movable stage that is an amount of movement at the output compared to an amount of movement at the movable stage.
6. The system of clause 5, wherein the angle between the input and the output is 120 degrees thereby causing the ratio to be 1.
7. The system of clause 1, further comprising:
an objective for receiving the output, the objective configured to move with the movable stage in a first direction; and
a first static mirror configured to direct the beam to the objective,
wherein moving the movable stage and the objective along the first direction retains the position of the output at the objective along a second direction.
8. The system of clause 7, wherein the objective is mechanically coupled to the movable stage.
9. The system of clause 7, wherein the objective is electronically controlled to move correspondingly to movement of the movable stage.
10. The system of clause 7, wherein movement of the movable stage in the second direction causes a corresponding movement of the output relative to objective.
11. The system of clause 1, further comprising:
an objective for receiving the output, the objective configured to move with the movable stage in a first direction and/or a second direction; and
a first static mirror configured to redirect the beam to the objective;
a second static mirror configured to direct the beam to the first static mirror,
wherein moving the movable stage and the objective to maintain a displacement along the first direction and along the second direction retains a position of the output at the objective.
12. The system of clause 7, further comprising:
a second static mirror configured to direct the beam to the mirror set;
a second mirror set oriented perpendicular to and out of a plane of the mirror set and configured to direct the beam from the second mirror set to the mirror set;
a second movable stage to which the second mirror set is mounted;
a third static mirror configured to direct the beam from the second mirror set to the second static mirror,
wherein moving the second mirror set in the first direction allows adjustment of the output in the first direction, moving the second mirror set in the second direction allows adjustment of the output in the second direction, and moving the second mirror set in the third direction does not change a location of the output in the third direction.
13. The system of clause 12, wherein the system is configured for the second mirror set and the objective to move in the second direction relative to the mirror set, thereby causing the output to move along the second direction.
14. The system of clause 12, wherein the objective is further configured to move in the second direction independently of the mirror set, wherein maintaining a displacement between the second mirror set and the objective in the second direction retains the position of the output relative to the objective in the second direction.
15. The system of clause 1, further comprising:
an objective for receiving the output, the objective configured to move with the movable stage to maintain a same displacement between the objective and the movable stage in both a first direction and a third direction;
a first static mirror configured to direct the beam to the objective;
a second static mirror configured to direct the beam to the first static mirror; and a folding mirror coupled to the movable stage and configured to turn the beam to be along a second direction;
wherein moving the movable stage and the objective to maintain the displacement retains a position of the output at the objective along the second direction.

The concepts disclosed herein may simulate or mathematically model any generic imaging system for imaging sub wavelength features and may be especially useful with emerging imaging technologies capable of producing increasingly shorter wavelengths. Emerging technologies already in use include EUV (extreme ultraviolet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-50 nm by using a synchrotron or by hitting a material (either solid or a plasma) with high energy electrons in order to produce photons within this range.

While the concepts disclosed herein may be used for imaging on a substrate such as a silicon wafer, it shall be understood that the disclosed concepts may be used with any type of lithographic imaging systems, e.g., those used for imaging on substrates other than silicon wafers.

The combinations and sub-combinations of the elements disclosed herein constitute separate embodiments and are provided as examples only. Also, the descriptions above are intended to be illustrative, not limiting. Thus, it will be apparent to one skilled in the art that modifications may be made as described without departing from the scope of the claims set out below.

1. A system comprising:
a mirror set comprising a first mirror and a second mirror; and
a movable stage to which the mirror set is mounted to cause the first mirror and the second mirror to move together with the movable stage,
wherein the first mirror is configured to receive a beam at a first angle from an axis of the mirror set,
wherein the second mirror is configured to provide the beam at a second angle from the axis of the mirror set, the beam providing an output after reflection by the second mirror,
wherein movement of the mirror set parallel to the axis results in a parallel shift of the output along the beam, and
wherein movement of the mirror set perpendicular to the axis results in a perpendicular shift of the output perpendicular to the beam.

2. The system of claim 1, wherein the beam is a light beam from a light source in an optical scanning device.

3. The system of claim 2, wherein the output is a focus point of the light beam.

4. The system of claim 1, further comprising an objective to receive the output and configured to move with the movable stage, wherein during movement of the movable stage and objective the output remains stationary with respect to the objective.

5. The system of claim 1, wherein an angular ratio that is a ratio between the first angle and the second angle determines a movement ratio of the movable stage that is an amount of movement at the output compared to an amount of movement at the movable stage.

6. The system of claim 5, wherein the beam received by the first mirror is an input and wherein the angle between the input and the output is 120 degrees thereby causing the angular ratio to be 1.

7. The system of claim 1, further comprising:
an objective to receive the output, the objective configured to move with the movable stage in a first direction; and
a first static mirror configured to direct the beam to the objective,
wherein movement of the movable stage and the objective along the first direction retains the position of the output at the objective along a second direction.

8. The system of claim 7, wherein the objective is mechanically coupled to the movable stage.

9. The system of claim 7, wherein the objective is electronically controlled to move correspondingly to movement of the movable stage.

10. The system of claim 7, wherein movement of the movable stage in the second direction causes a corresponding movement of the output relative to objective.

11. The system of claim 1, further comprising:
an objective to receive the output, the objective configured to move with the movable stage in a first direction and/or a second direction; and
a first static mirror configured to redirect the beam to the objective;
a second static mirror configured to direct the beam to the first static mirror,
wherein movement of the movable stage and the objective to maintain a displacement along the first direction and along the second direction retains a position of the output at the objective.

12. The system of claim 7, further comprising:
a second static mirror configured to direct the beam to the mirror set;
a second mirror set oriented perpendicular to and out of a plane of the mirror set and configured to direct the beam from the second mirror set to the mirror set;
a second movable stage to which the second mirror set is mounted;
a third static mirror configured to direct the beam from the second mirror set to the second static mirror,
wherein movement of the second mirror set in the first direction allows adjustment of the output in the first direction, movement of the second mirror set in the second direction allows adjustment of the output in the second direction, and movement of the second mirror set in a third direction does not change a location of the output in the third direction.

13. The system of claim 12, wherein the system is configured for the second mirror set and the objective to move in the second direction relative to the mirror set, to cause the output to move along the second direction.

14. The system of claim 12, wherein the objective is further configured to move in the second direction independently of the mirror set, wherein maintenance of a displacement between the second mirror set and the objective in the second direction retains the position of the output relative to the objective in the second direction.

15. The system of claim 1, further comprising:
an objective to receive the output, the objective configured to move with the movable stage to maintain a same displacement between the objective and the movable stage in both a first direction and a third direction;
a first static mirror configured to direct the beam to the objective;
a second static mirror configured to direct the beam to the first static mirror; and
a folding mirror coupled to the movable stage and configured to turn the beam to be along a second direction,
wherein movement of the movable stage and the objective to maintain the displacement retains a position of the output at the objective along the second direction.

16. A method comprising:
receiving, at a first mirror, a beam at a first angle from an axis of a mirror set, the mirror set comprising the first mirror and a second mirror; and
providing an output of the beam after reflection of the beam from the second mirror at a second angle from the axis of the mirror set,
wherein moving the mirror set together parallel to the axis results in a parallel shift of the output along the beam, and
wherein moving the mirror set together perpendicular to the axis results in a perpendicular shift of the output perpendicular to the beam.

17. The method of claim 16, wherein the beam is a light beam from a light source in an optical scanning device.

18. The method of claim 17, wherein the output is a focus point of the light beam.

19. The method of claim 16, further comprising receiving the output at an objective, wherein during movement of the mirror set and the objective the output remains stationary with respect to the objective.

20. The method of claim 16, further comprising:
receiving the output at an objective configured to move in a first direction; and
directing the beam to the objective using a first static mirror,
wherein moving the mirror set and the objective along the first direction retains the position of the output at the objective along a second direction.
